(19) United States
(12) Patent Application Publication
(10) Pub. No.: US 2026/0247820 A1
(43) Pub. Date: Aug. 20, 2026

(54) PIXEL CIRCUIT, AND DISPLAY SUBSTRATE AND DARK SPOT REPAIR METHOD THEREFOR

(71) Applicants: Hefei BOE Joint Technology Co.,Ltd., Hefei, Anhui (CN); BOE Technology Group Co., Ltd., Beijing (CN); Beijing BOE Technology Development Co., Ltd., Beijing (CN)

(72) Inventors: Can YUAN, Beijing (CN); Yongqian LI, Beijing (CN); Xinxin WANG, Beijing (CN); Xiang WAN, Beijing (CN); Zhidong YUAN, Beijing (CN); Xiuting LIU, Beijing (CN); Xiangze ZHANG, Beijing (CN); Dandan ZHOU, Beijing (CN)

(21) Appl. No.: 19/480,378

(22) PCT Filed: Oct. 12, 2024
(86) PCT No.: PCT/CN2024/124414

§ 371 Date: Oct. 31, 2025

(30) Foreign Application Priority Data
Apr. 18, 2024 (CN) 202410467999.4

(51) Int. Cl. H10K 59/131; H10K 59/121; H10K 59/122; H10K 71/00

(52) U.S. Cl. CPC H10K 59/131; H10K 59/121; H10K 59/122; H10K 71/861

(57) ABSTRACT

Provided are a pixel circuit, and a display substrate and a dark spot repair method therefor. Each pixel unit in a pixel circuit comprises at least two pixel light-emitting branches; in pixel light-emitting branches (A, B, C, D) of a same pixel unit, light-emitting elements of a same color are connected in parallel; and a first-type metal electrode (1021) is bridged with a first electrode (102) of a first color light-emitting element of each of at least two pixel light-emitting branches (A, B, C, D), a second-type metal electrode (1041) is bridged with a first electrode (104) of a second color light-emitting element of each of the at least two pixel light-emitting branches (A, B, C, D), and a third-type metal electrode (1061) is bridged with a first electrode (106) of a third color light-emitting element of each of the at least two pixel light-emitting branches (A, B, C, D).

### CROSS-REFERENCE TO RELATED APPLICATIONS

The present application is a U.S. National Phase Entry of International Application No. PCT/CN 2024/124414 having an international filing date of Oct. 12, 2024, which claims the priority to Chinese patent application No. 202410467999.4, filed to the CNIPA on Apr. 18, 2024, contents of the above-identified applications should be interpreted as being incorporated into the present application by reference.

### TECHNICAL FIELD

Embodiments of the present disclosure relate to, but are not limited to, the field of display technologies, and particularly relate to a pixel circuit, a display substrate, and a dark spot repair method therefor.

### BACKGROUND

An Organic Light Emitting Diode (OLED) display substrate is an active light emitting device, which has attracted more and more attention because of its advantages such as high contrast, a wide viewing angle, low power consumption, lightness and thinness.

The OLED display substrate usually is of a hierarchical structure, and an OLED light emitting element used for achieving a light emitting function in the OLED display substrate generally includes an electroluminescent layer for emitting light of a specific color, and an anode layer and a cathode layer respectively disposed at two sides of the electroluminescent layer. When a voltage between the anode layer and the cathode layer is higher than a turn-on voltage of the light emitting element, the electroluminescent layer in the light emitting element is excited to emit light.

During a manufacturing process of the OLED display substrate, residual conductive particles may be easily lead to a short circuit occurs between the anode layer and the cathode layer of the OLED light emitting element inside the display substrate, so that there is no voltage difference between the anode layer and the cathode layer, and the electroluminescent layer cannot emit light, resulting in dark spots in s corresponding pixel structure, which affects a product yield adversely.

### SUMMARY

The following is a summary of subject matters described herein in detail. This summary is not intended to limit the protection scope of claims.

Embodiments of the present disclosure provide a pixel circuit, a display substrate, and a dark spot repair method therefor.

In a first aspect, a pixel circuit is provided in an embodiment of the present disclosure. The pixel circuit includes: a plurality of pixel units, wherein a pixel unit of the plurality of pixel units includes at least two pixel light emitting branches; a pixel light emitting branch of the at least two pixel light emitting branches includes at least two of a first color light emitting element, a second color light emitting element, and a third color light emitting element; in each pixel light emitting branch of a same pixel unit, light emitting elements of a same color are connected in parallel; the pixel unit further includes a first type metal electrode, a second type metal electrode, and a third type metal electrode, wherein the first type metal electrode is used to be connected to an electrode voltage of the first color light emitting element, the second type metal electrode is used to be connected to an electrode voltage of the second color light emitting element, and the third type metal electrode is used to be connected to an electrode voltage of the third color light emitting element; the first type metal electrode bridges first electrodes of first color light emitting elements of at least two pixel light emitting branches, the second type metal electrode bridges first electrodes of second color light emitting elements of at least two pixel light emitting branches, and the third type metal electrode bridges first electrodes of third color light emitting elements of at least two pixel light emitting branches.

Optionally, the pixel unit includes two pixel light emitting branches; the first type metal electrode bridges a first electrode of a first color light emitting element of each of the two pixel light emitting branches, the second type metal electrode bridges a first electrode of a second color light emitting element of each of the two pixel light emitting branches, and the third type metal electrode bridges a first electrode of a third color light emitting element of each of the two pixel light emitting branches.

Optionally, the pixel unit includes three pixel light emitting branches; the first type metal electrode bridges first electrodes of first color light emitting elements of at least two of the three pixel light emitting branches, the second type metal electrode bridges first electrodes of second color light emitting elements of at least two of the three pixel light emitting branches, and the third type metal electrode bridges first electrodes of third color light emitting elements of at least two of the three pixel light emitting branches.

Optionally, the pixel circuit includes four pixel light emitting branches; first electrodes of light emitting elements of a same color in the four pixel light emitting branches are connected with each other through metal traces; the first type metal electrode bridges first electrodes of first color light emitting elements of two of the four pixel light emitting branches, the second type metal electrode bridges first electrodes of second color light emitting elements of two of the four pixel light emitting branches, and the third type metal electrode bridges first electrodes of third color light emitting elements of two of the four pixel light emitting branches.

Optionally, the pixel circuit includes four pixel light emitting branches; the first type metal electrode bridges a first electrode of a first color light emitting element of each of the four pixel light emitting branches, the second type metal electrode bridges a first electrode of a second color light emitting element of each of the four pixel light emitting branches, and the third type metal electrode bridges a first electrode of a third color light emitting element of each of the four pixel light emitting branches.

Optionally, the four pixel light emitting branches include a first pixel light emitting branch, a second pixel light emitting branch, a third pixel light emitting branch, and a fourth pixel light emitting branch; the pixel unit includes two first type metal electrodes, wherein one first type metal electrode bridges first electrodes of first color light emitting elements in the first pixel light emitting branch and the second pixel light emitting branch, and the other first type metal electrode bridges first electrodes of first color light emitting elements in the third pixel light emitting branch and the fourth pixel light emitting branch; the pixel unit includes two second type metal electrodes, wherein one second type metal electrode bridges first electrodes of second color light emitting elements in the second pixel light emitting branch and the fourth pixel light emitting branch, and the other second type metal electrode bridges first electrodes of second color light emitting elements in the first pixel light emitting branch and the third pixel light emitting branch; the pixel unit includes two third type metal electrodes, wherein one third type metal electrode bridges first electrodes of third color light emitting elements in the first pixel light emitting branch and the third pixel light emitting branch, and the other third type metal electrode bridges first electrodes of third color light emitting elements in the second pixel light emitting branch and the fourth pixel light emitting branch.

Optionally, a first color light emitting element, a second color light emitting element, and a third color light emitting element in a same pixel light emitting branch are stacked and arranged.

In a second aspect, a display substrate is provided in an embodiment of the present disclosure. The display substrate includes a base substrate and at least two pixel units disposed on the base substrate.

A pixel unit of the at least two pixel units includes a first metal layer, a first electroluminescent layer, a second metal layer, a second electroluminescent layer, a third metal layer, a third electroluminescent layer, a fourth metal layer, and a pixel definition layer; the first metal layer is disposed on the base substrate, the first electroluminescent layer is disposed at a side of the first metal layer away from the base substrate, the second metal layer is disposed at a side of the first electroluminescent layer away from the base substrate, the second electroluminescent layer is disposed at a side of the second metal layer away from the base substrate, the third metal layer is disposed at a side of the second electroluminescent layer away from the base substrate, the third electroluminescent layer is disposed at a side of the third metal layer away from the base substrate, and the fourth metal layer is disposed at a side of the third electroluminescent layer away from the base substrate; the first metal layer, the first electroluminescent layer, the second metal layer, the second electroluminescent layer, the third metal layer, the third electroluminescent layer, and the fourth metal layer are defined as a plurality of pixel light emitting branches by the pixel definition layer; a pixel light emitting branch of the plurality of pixel light emitting branches includes a first color light emitting element, a second color light emitting element, and a third color light emitting element; in each pixel light emitting branch of a same pixel unit, light emitting elements of a same color are connected in parallel; the pixel unit further includes a first type metal electrode, a second type metal electrode, and a third type metal electrode, wherein the first type metal electrode bridges first metal layers of at least two pixel light emitting branches, the second type metal electrode bridges second metal layers of at least two pixel light emitting branches, and the third type metal electrode bridges third metal layers of at least two pixel light emitting branches.

Optionally, the first metal layer, the first electroluminescent layer, the second metal layer, the second electroluminescent layer, the third metal layer, the third electroluminescent layer, and the fourth metal layer are defined as two pixel light emitting branches by the pixel definition layer; the first type metal electrode is located in the first metal layer; the second type metal electrode is located in the second metal layer; and the third type metal electrode is located in the third metal layer; the first type metal electrode bridges a first metal layer of each of the two pixel light emitting branches; the second type metal electrode bridges a second metal layer of each of the two pixel light emitting branches; and the third type metal electrode bridges a third metal layer of each of the two pixel light emitting branches.

Optionally, the first metal layer, the first electroluminescent layer, the second metal layer, the second electroluminescent layer, the third metal layer, the third electroluminescent layer, and the fourth metal layer are defined as three pixel light emitting branches by the pixel definition layer; the first type metal electrode is located in the first metal layer; the second type metal electrode is located in the second metal layer; and the third type metal electrode is located in the third metal layer; first metal layers in the three pixel light emitting branches are connected with each other through metal traces; second metal layers in the three pixel light emitting branches are connected with each other through metal traces; and third metal layers in the three pixel light emitting branches are connected with each other through metal traces; the first type metal electrode bridges first metal layers of two of the three pixel light emitting branches; the second type metal electrode bridges second metal layers of two of the three pixel light emitting branches; and the third type metal electrode bridges third metal layers of two of the three pixel light emitting branches.

Optionally, the first metal layer, the first electroluminescent layer, the second metal layer, the second electroluminescent layer, the third metal layer, the third electroluminescent layer, and the fourth metal layer are defined as four pixel light emitting branches by the pixel definition layer; the first type metal electrode is located in the first metal layer; the second type metal electrode is located in the second metal layer; and the third type metal electrode is located in the third metal layer; first metal layers in the four pixel light emitting branches are connected with each other through metal traces; second metal layers in the four pixel light emitting branches are connected with each other through metal traces; and third metal layers in the four pixel light emitting branches are connected with each other through metal traces; the first type metal electrode bridges first metal layers of at least two of the four pixel light emitting branches; the second type metal electrode bridges second metal layers of at least two of the four pixel light emitting branches; and the third type metal electrode bridges third metal layers of at least two of the four pixel light emitting branches.

Optionally, the first metal layer is defined by the pixel definition layer as a first first metal region included in a first pixel light emitting branch, a second first metal region included in a second pixel light emitting branch, a third first metal region included in a third pixel light emitting branch, and a fourth first metal region included in a fourth pixel light emitting branch; the second metal layer is defined by the pixel definition layer as a first second metal region included in the first pixel light emitting branch, a second second metal region included in the second pixel light emitting branch, a third second metal region included in the third pixel light emitting branch, and a fourth second metal region included in the fourth pixel light emitting branch; the third metal layer is defined by the pixel definition layer as a first third metal region included in the first pixel light emitting branch, a second third metal region included in the second pixel light emitting branch, a third third metal region included in the third pixel light emitting branch, and a fourth third metal region included in the fourth pixel light emitting branch; the first type metal electrode is located in the first metal layer, the second type metal electrode is located in the second metal layer, and the third type metal electrode is located in the third metal layer; the first first metal region and the second first metal region are connected through a metal trace, the second first metal region and the third first metal region are connected through a metal trace, the third first metal region and the fourth first metal region are connected through a metal trace, and the fourth first metal region and the first first metal region are connected through a metal trace; the first second metal region and the second second metal region are connected through a metal trace, the second second metal region and the third second metal region are connected through a metal trace, the third second metal region and the fourth second metal region are connected through a metal trace, and the fourth second metal region and the first second metal region are connected through a metal trace; the first third metal region and the second third metal region are connected through a metal trace, the second third metal region and the third third metal region are connected through a metal trace, the third third metal region and the fourth third metal region are connected through a metal trace, and the fourth third metal region and the first third metal region are connected through a metal trace; the first type metal electrode bridges the first first metal region and the second first metal region, the second type metal electrode bridges the second second metal region and the fourth second metal region, and the third type metal electrode bridges the first third metal region and the third third metal region.

Optionally, the first metal layer is defined by the pixel definition layer as a first first metal region included in a first pixel light emitting branch, a second first metal region included in a second pixel light emitting branch, a third first metal region included in a third pixel light emitting branch, and a fourth first metal region included in a fourth pixel light emitting branch; the second metal layer is defined by the pixel definition layer as a first second metal region included in the first pixel light emitting branch, a second second metal region included in the second pixel light emitting branch, a third second metal region included in the third pixel light emitting branch, and a fourth second metal region included in the fourth pixel light emitting branch; the third metal layer is defined by the pixel definition layer as a first third metal region included in the first pixel light emitting branch, a second third metal region included in the second pixel light emitting branch, a third third metal region included in the third pixel light emitting branch, and a fourth third metal region included in the fourth pixel light emitting branch; the first type metal electrode is located in the first metal layer, the second type metal electrode is located in the second metal layer, and the third type metal electrode is located in the third metal layer; the pixel unit includes two first type metal electrodes, wherein one first type metal electrode bridges the first first metal region and the second first metal region, and the other first type metal electrode bridges the third first metal region and the fourth first metal region; the pixel unit includes two second type metal electrodes, wherein one second type metal electrode bridges the second second metal region and the fourth second metal region, and the other second type metal electrode bridges the first second metal region and the third second metal region; the pixel unit includes two third type metal electrodes, wherein one third type metal electrode bridges the first third metal region and the third third metal region, and the other third type metal electrode bridges the second third metal region and the fourth third metal region.

Optionally, the fourth metal layer is distributed on an entire surface.

In a third aspect, an embodiment of the present disclosure provides a dark spot repair method of a display substrate, applied to the display substrate according to any embodiment of the present disclosure, and the method includes: determining a short-circuited pixel light emitting branch in the display substrate; and cutting off an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage; wherein the electrode voltage includes an electrode voltage to which the first metal layer is connected, an electrode voltage to which the second metal layer is connected, and an electrode voltage to which the third metal layer is connected.

Optionally, the cutting off the electrical connection between the light emitting element of each color in the short-circuited pixel light emitting branch and the light emitting element of the remaining pixel light emitting branch in the pixel unit, and the electrical connection between the short-circuited pixel light emitting branch and the electrode voltage, includes: cutting off a metal trace between a first metal region in the short-circuited pixel light emitting branch and a first metal region of the remaining pixel light emitting branch in the pixel unit; cutting off a metal trace between a second metal region in the short-circuited pixel light emitting branch and a second metal region of the remaining pixel light emitting branch in the pixel unit; cutting off a metal trace between a third metal region in the short-circuited pixel light emitting branch and a third metal region of the remaining pixel light emitting branch in the pixel unit; and cutting off a first type metal electrode bridged by a first metal layer in the short-circuited pixel light emitting branch, a second type metal electrode bridged by a second metal layer in the short-circuited pixel light emitting branch, and a third type metal electrode bridged by a third metal layer in the short-circuited pixel light emitting branch.

Optionally, the cutting off the electrical connection between the light emitting element of each color in the short-circuited pixel light emitting branch and the light emitting element of the remaining pixel light emitting branch in the pixel unit, and the electrical connection between the short-circuited pixel light emitting branch and the electrode voltage, includes: cutting off a first type metal electrode bridged by a first metal layer in the short-circuited pixel light emitting branch, a second type metal electrode bridged by a second metal layer in the short-circuited pixel light emitting branch, and a third type metal electrode bridged by a third metal layer in the short-circuited pixel light emitting branch.

Other features and advantages of the present disclosure will be set forth in the following specification, and moreover, partially become apparent from the specification, or are understood by implementing the present disclosure. Other advantages of the present disclosure may be achieved and obtained through solutions described in the specification and drawings.

Other aspects may be comprehended after drawings and detailed description are read and understood.

### BRIEF DESCRIPTION OF DRAWINGS

Accompanying drawings used in the embodiments of the present disclosure will be briefly introduced hereinafter. The drawings are used to provide an understanding of technical solutions of the present disclosure, constitute a part of the specification, and explain the technical solutions of the present disclosure together with the embodiments of the present disclosure, but are not intended to constitute limitations on the technical solutions of the present disclosure. For those skilled in the art, other embodiments may be obtained according to these drawings without paying creative labor.

FIG. 1 is an equivalent circuit diagram of a pixel circuit according to an embodiment of the present disclosure.

FIG. 2 is an equivalent circuit diagram of another pixel circuit according to an embodiment of the present disclosure.

FIG. 3 is an equivalent circuit diagram of yet another pixel circuit according to an embodiment of the present disclosure.

FIG. 4 is a schematic diagram of a film layer structure of a display substrate according to an embodiment of the present disclosure.

FIG. 5 is a schematic diagram of a planar structure of a display substrate according to an embodiment of the present disclosure.

FIG. 6 is a schematic diagram of another film layer structure of a display substrate according to an embodiment of the present disclosure.

FIG. 7 is a schematic diagram of performing dark spot repair on a display substrate according to an embodiment of the present disclosure.

FIG. 8 is a schematic diagram of a first metal layer of a display substrate according to an embodiment of the present disclosure.

FIG. 9 is a schematic diagram of a first metal layer and a pixel definition layer of a display substrate according to an embodiment of the present disclosure.

FIG. 10 is a schematic diagram of a first metal layer, a pixel definition layer, and a first electroluminescent layer of a display substrate according to an embodiment of the present disclosure.

FIG. 11 is a schematic diagram of a first metal layer, a pixel definition layer, a first electroluminescent layer, and a second metal layer of a display substrate according to an embodiment of the present disclosure.

FIG. 12 is a schematic diagram of a first metal layer, a pixel definition layer, a second metal layer, and a third metal layer of a display substrate according to an embodiment of the present disclosure.

FIG. 13 is a schematic diagram of a planar structure of another display substrate according to an embodiment of the present disclosure.

FIG. 14 is a schematic diagram of yet another film layer structure of a display substrate according to an embodiment of the present disclosure.

FIG. 15 is a schematic diagram of performing dark spot repair on another display substrate according to an embodiment of the present disclosure.

FIG. 16 is a schematic diagram of a first metal layer of another display substrate according to an embodiment of the present disclosure.

FIG. 17 is a schematic diagram of a first metal layer and a pixel definition layer of another display substrate according to an embodiment of the present disclosure.

FIG. 18 is a schematic diagram of a first metal layer, a pixel definition layer, and a second metal layer of another display substrate according to an embodiment of the present disclosure.

FIG. 19 is a schematic diagram of a first metal layer, a pixel definition layer, a second metal layer, and a third metal layer of another display substrate according to an embodiment of the present disclosure.

FIG. 20 is a schematic diagram of a planar structure of yet another display substrate according to an embodiment of the present disclosure.

FIG. 21 is a schematic diagram of performing dark spot repair on yet another display substrate according to an embodiment of the present disclosure.

FIG. 22 is a schematic diagram of a planar structure of yet another display substrate according to an embodiment of the present disclosure.

FIG. 23 is a schematic diagram of performing dark spot repair on yet another display substrate according to an embodiment of the present disclosure.

FIG. 24 is a schematic flowchart of a dark spot repair method according to an embodiment of the present disclosure.

### DETAILED DESCRIPTION

The technical solutions in the embodiments of present disclosure will be described clearly and completely with reference to the drawings in the embodiments of present disclosure. Obviously, the described embodiments are only part of the embodiments of the present disclosure, rather than all of the embodiments. Based on the embodiments in the present disclosure, all other embodiments obtained by those of ordinary skill in the art based on the present disclosure fall within the scope of protection of the present disclosure.

Unless otherwise defined, technical terms or scientific terms used in the present disclosure should have meanings as commonly understood by those of ordinary skills in the field to which the present disclosure belongs to. The term “first”, “second”, and similar words used in the present disclosure do not indicate any order, quantity, or importance, but are used only for distinguishing different components. “Include”, “contain”, or a similar word means that elements or objects appearing before the word cover elements or objects listed after the word and their equivalents, but do not exclude other elements or objects. “Connect”, “couple”, or a similar word is not limited to a physical or mechanical connection, but may include an electrical connection, whether direct or indirect. “Upper”, “lower”, “left”, and “right”, etc., are only used for representing a relative positional relationship, and when an absolute position of a described object is changed, the relative positional relationship may also be correspondingly changed.

Sizes of a plurality of patterns in a display substrate involved in an embodiment of the present disclosure are generally of the order of microns or less in actual products. For the sake of clarity, sizes of one or more structures in the drawings of the embodiments of the present disclosure are enlarged, and do not represent actual sizes and proportions unless explicitly stated otherwise.

Since a laminated OLED device has a large number of electrodes, control of conductive particles in a device preparation process is relatively strict. When a local short circuit between electrodes in the device is caused by the conductive particles, it leads to dark spot defects in the OLED device. This phenomenon will affect a product yield of produced OLED devices adversely.

A pixel circuit and a corresponding display substrate are provided in embodiments of the present disclosure. In an exemplary embodiment of the present disclosure, a device is divided into blocks, one pixel is divided into different light emitting regions according to a quantity of electrodes in the pixel, and a design in which electrode branches of the light emitting regions may be repaired is adopted, so that on a basis of ensuring that different light emitting regions in the pixel can emit light, dark spot repair on the regions can be achieved. Therefore, in an actual production scenario, in view of a problem that a produced device is determined to be an unqualified product due to dark spot defects, the device may be repaired into a qualified device by performing dark spot repair on the device, thereby improving product quality and a yield.

Furthermore, in the exemplary embodiment of the present disclosure, the design of dividing the device into blocks and ensuring that different light emitting regions in the pixel can emit light is adopted, and distribution of elements in the device and a mode of driving electrodes in the device are optimized, thereby providing technical support for ultra-high Pixels Per Inch (PPI, a pixel density unit) products, and having broad application prospects.

A pixel circuit is provided in an embodiment of the present disclosure, and the pixel circuit may include: a plurality of pixel units, wherein a pixel unit may include at least two pixel light emitting branches; a pixel light emitting branch may include at least two of a first color light emitting element, a second color light emitting element, and a third color light emitting element; in pixel light emitting branches of a same pixel unit, light emitting elements of a same color are connected in parallel; the pixel unit may further include a first type metal electrode, a second type metal electrode, and a third type metal electrode, wherein the first type metal electrode is configured to be connected to an electrode voltage of the first color light emitting element, the second type metal electrode is configured to be connected to an electrode voltage of the second color light emitting element, and the third type metal electrode is configured to be connected to an electrode voltage of the third color light emitting element; the first type metal electrode bridges first electrodes of first color light emitting elements of at least two pixel light emitting branches, the second type metal electrode bridges first electrodes of second color light emitting elements of at least two pixel light emitting branches, and the third type metal electrode bridges first electrodes of third color light emitting elements of at least two pixel light emitting branches.

For example, light emitting elements of each color of a predetermined plurality of colors are usually provided in the pixel circuit, and color display is performed based on these light emitting elements of different colors. In an embodiment of the present disclosure, light emitting elements involved in a pixel circuit may include a first color light emitting element, a second color light emitting element, and a third color light emitting element. In some exemplary embodiments, when a Red Green Blue (RGB) format is adopted for display for the pixel circuit, the first color light emitting element may be a red light emitting element that emits red (R) light, the second color light emitting element may be a blue light emitting element that emits blue (B) light, and the third color light emitting element may be a green light emitting element that emits green (G) light.

In the pixel circuit according to the present disclosure, each pixel unit has a plurality of pixel light emitting branches. Furthermore, each pixel light emitting branch has an ability to independently achieve a light emitting function. Furthermore, in a case of short circuit of electrodes in any pixel light emitting branch in the pixel unit, in order to achieve independent control of a remaining pixel light emitting branch, first electrodes of light emitting elements of a same color in different pixel light emitting branches are designed to be separated from each other.

In a practical application, a first electrode of the first color light emitting element, a first electrode of the second color light emitting element, and a first electrode of the third color light emitting element may be connected to a specific electrode voltage, so that each light emitting element can be driven to emit light. In a possible implementation mode, the first electrode refers to an anode of a light emitting element. Or, in another possible implementation mode, the first electrode may refer to a cathode of a light emitting element.

For example, an electrical signal of an electrode voltage may be introduced to a light emitting element through a metal electrode. Herein, in the embodiment of the present disclosure, a metal electrode for connecting the electrode voltage of the first color light emitting element is referred to as a first type metal electrode, a metal electrode for connecting the electrode voltage of the second color light emitting element is referred to as a second type metal electrode, and a metal electrode for connecting the electrode voltage of the third color light emitting element is referred to as a third type metal electrode.

In the pixel circuit according to the embodiment of the present disclosure, in order to achieve isolation of any pixel light emitting branch in the pixel unit and ensure that other pixel light emitting branches can work normally under a condition that the any pixel light emitting branch in the pixel unit has a short-circuit problem, the first type metal electrode bridges first electrodes of first color light emitting elements of at least two pixel light emitting branches in the pixel unit, the second type metal electrode bridges first electrodes of second color light emitting elements of at least two pixel light emitting branches in the pixel unit, and the third type metal electrode bridges first electrodes of third color light emitting elements of at least two pixel light emitting branches in the pixel unit. Furthermore, for each pixel unit, light emitting elements of a same color in one or more pixel light emitting branches may be of a parallel structure, so that under a condition that a first electrode of a light emitting element is not directly connected to a corresponding electrode voltage through a metal electrode, the first electrode of the light emitting element may receive an electrical signal of the corresponding electrode voltage via another light emitting element connected with itself in parallel, and achieve a light emitting function.

In this way, in the pixel circuit according to the exemplary embodiment of the present disclosure, it may be ensured that after a metal electrode introduces an electrical signal into a corresponding pixel light emitting branch, light emitting elements in different pixel light emitting branches can cooperate with each other by means of a parallel structure to achieve a light emitting function. Furthermore, in a case where a short circuit problem occurs in any one pixel light emitting branch in the pixel unit, isolation of the pixel light emitting branch may be achieved by cutting off an electrical connection between a light emitting element of each color in the pixel light emitting branch and a light emitting element of a remaining pixel light emitting branch, and cutting off an electrical connection between a first electrode of each color light emitting element in the pixel light emitting branch and a corresponding electrode voltage. Furthermore, since each type metal electrode bridges first electrodes of corresponding color light emitting elements in at least two pixel light emitting branches, for a light emitting element of each color, even if a metal electrode connected with a light emitting element of the color in the pixel light emitting branch where the short-circuit problem occurs is cut off, there is still a light emitting element of the color in at least one pixel light emitting branch in the pixel unit, and the light emitting element of the color can directly receive an electrical signal of a corresponding electrode voltage through a metal electrode, and can transmit the electrical signal to a light emitting element of the color in a remaining pixel light emitting branch without a metal electrode through a parallel structure between light emitting elements. That is to say, after the pixel light emitting branch with the short-circuit problem is isolated, the remaining pixel light emitting branch in the pixel unit can still achieve a light emitting function normally, thus achieving an effect of dark spot repair, and further improving a product yield in a production scenario of a display device. Furthermore, in the exemplary embodiment of the present disclosure, a design in which the pixel unit is divided into different pixel light emitting branches and each of different pixel light emitting branches in the pixel unit can emit light is adopted, and distribution of elements in the device and a mode of driving electrodes in the device are optimized, thereby providing technical support for ultra-high PPI products.

In order to facilitate understanding, the pixel circuit according to the present disclosure will be described below in combination with several exemplary embodiments.

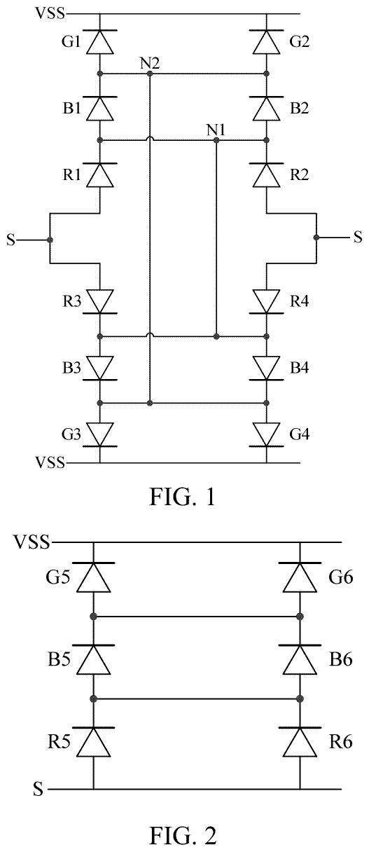

In some exemplary embodiments, as shown in FIG. 1, a pixel circuit is provided in an exemplary embodiment of the present disclosure. In the pixel circuit, each pixel unit includes four pixel light emitting branches. Herein, a first color light emitting element R1, a second color light emitting element B1, and a third color light emitting element G1 may constitute one pixel light emitting branch. A first color light emitting element R2, a second color light emitting element B2, and a third color light emitting element G2 may constitute another pixel light emitting branch. A first color light emitting element R3, a second color light emitting element B3, and a third color light emitting element G3 may constitute yet another pixel light emitting branch. A first color light emitting element R4, a second color light emitting element B4, and a third color light emitting element G4 may constitute yet another pixel light emitting branch.

In some exemplary embodiments, light emitting elements of a same color in a plurality of pixel light emitting branches in the pixel unit are in a parallel structure. For example, as shown in FIG. 1, light emitting elements of a same color in four pixel light emitting branches shown in FIG. 1 are in a parallel structure. In the four pixel light emitting branches, all first electrodes of the first color light emitting elements R1, R2, R3, and R4 are connected to a voltage S and in a parallel structure, first electrodes of the second color light emitting elements B1, B2, B3, and B4 are connected in parallel and meet at a first potential point N1, and first electrodes of the third color light emitting elements G1, G2, G3, and G4 are connected in parallel and meet at a second potential point N2. Furthermore, second electrodes of the third color light emitting elements G1, G2, G3, and G4 may be connected to a power supply negative electrode VSS.

In some exemplary embodiments, for light emitting elements of each color, a metal electrode (not shown in the figure) is disposed on a first electrode of a light emitting component of the color in at least two pixel light emitting branches among the four pixel light emitting branches shown in FIG. 1, and a corresponding electrode voltage is connected through the metal electrode. In an actual pixel structure, light emitting elements of a same color in one or more pixel light emitting branches in a pixel unit may form a parallel structure through a metal electrode and cooperation between metal traces between electrodes of different light emitting elements.

In one possible implementation mode, a first type metal electrode bridges first electrodes of two of the first color light emitting elements R1, R2, R3, and R4, a second type metal electrode bridges first electrodes of two of the second color light emitting elements B1, B2, B3, and B4, and a third type metal electrode bridges first electrodes of two of the third color light emitting elements G1, G2, G3, and G4. First electrodes of the first color light emitting elements R1, R2, R3, and R4 are connected with each other through metal traces, first electrodes of the second color light emitting elements B1, B2, B3, and B4 are connected with each other through metal traces, and first electrodes of the third color light emitting elements G1, G2, G3, and G4 are connected with each other through metal traces.

In another possible implementation mode, each of the first electrodes of the first color light emitting elements R1, R2, R3, and R4 is connected with a first type metal electrode, each of the second color light emitting elements B1, B2, B3, and B4 is connected with a second type metal electrode, and each of the third color light emitting elements G1, G2, G3, and G4 is connected with a third type metal electrode.

In some exemplary embodiments, as shown in FIG. 2, another pixel circuit is also provided in an exemplary embodiment of the present disclosure. In the pixel circuit, each pixel unit includes two pixel light emitting branches. Herein a first color light emitting element R5, a second color light emitting element B5, and a third color light emitting element G5 may constitute one pixel light emitting branch, and a first color light emitting element R6, a second color light emitting element B6, and a third color light emitting element G6 may constitute another pixel light emitting branch.

In some exemplary embodiments, as shown in FIG. 2, a first type metal electrode bridges first electrodes of the first color light emitting elements R5 and R6, a second type metal electrode bridges first electrodes of the second color light emitting elements B5 and B6, and a third type metal electrode bridges first electrodes of the third color light emitting elements G5 and G6.

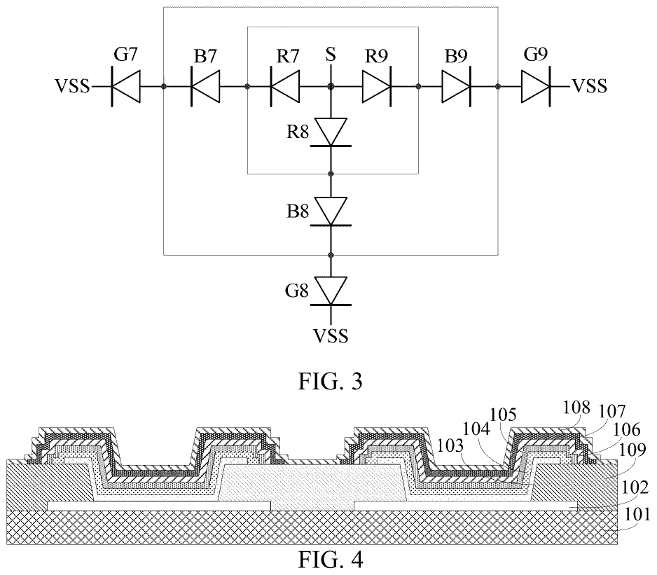

In some exemplary embodiments, as shown in FIG. 3, yet another pixel circuit is also provided in an exemplary embodiment of the present disclosure. In the pixel circuit, each pixel unit includes three pixel light emitting branches. Herein, a first color light emitting element R7, a second color light emitting element B7, and a third color light emitting element G7 may constitute one pixel light emitting branch. A first color light emitting element R8, a second color light emitting element B8, and a third color light emitting element G8 may constitute another pixel light emitting branch. A first color light emitting element R9, a second color light emitting element B9, and a third color light emitting element G9 may constitute yet another pixel light emitting branch.

In some exemplary embodiments, as shown in FIG. 3, the first color light emitting elements R7, R8, and R9 are connected in parallel with each other, the second color light emitting elements B7, B8, and B9 are connected in parallel with each other, and the third color light emitting elements G7, G8, and G9 are also connected in parallel with each other.

Moreover, a first type metal electrode bridges first electrodes of at least two of the first color light emitting elements R7, R8, and R9, a second type metal electrode bridges first electrodes of at least two of the second color light emitting elements B7, B8, and B9, and a third type metal electrode bridges first electrodes of at least two of the third color light emitting elements G7, G8, and G9. Besides, first electrodes of the first color light emitting elements R7, R8, and R9 may be connected with each other through metal traces, first electrodes of the second color light emitting elements B7, B8, and B9 may be connected with each other through metal traces, and first electrodes of the third color light emitting elements G7, G8, and G9 may be connected with each other through metal traces.

In this way, in the pixel circuit according to the embodiment of the present disclosure described above, a pixel unit is divided into different light emitting regions (that is, different pixel light emitting branches) according to a quantity of electrodes in the pixel unit, and each light emitting region has a first color light emitting element, a second color light emitting element, and a third color light emitting element. Electrodes of light emitting elements of a same color between light emitting regions of different pixels are separated correspondingly, and potential points between each device meet to form a parallel structure, which is convenient for repair when short circuit occurs in any subsequent light emitting region. How to achieve repair for dark spots under this architecture will be explained in subsequent embodiments of the display substrate.

Based on the embodiment of the pixel circuit described above, a display substrate is also provided in an embodiment of the present disclosure. FIG. 4 is a schematic diagram of a film layer structure of a display substrate according to an embodiment of the present disclosure, and FIG. 4 is illustrated by taking a film layer structure of one pixel unit of the display substrate as an example. As shown in FIG. 4, the display substrate includes a base substrate 101 and a plurality of pixel units disposed on the base substrate 101.

At least one of the plurality of pixel units includes a first metal layer 102, a first electroluminescent layer 103, a second metal layer 104, a second electroluminescent layer 105, a third metal layer 106, a third electroluminescent layer 107, a fourth metal layer 108, and a pixel definition layer 109.

The first metal layer 102 is disposed on the base substrate 101, the first electroluminescent layer 103 is disposed at a side of the first metal layer 102 away from the base substrate 101, the second metal layer 104 is disposed at a side of the first electroluminescent layer 103 away from the base substrate 101, the second electroluminescent layer 105 is disposed at a side of the second metal layer 104 away from the base substrate 101, the third metal layer 106 is disposed at a side of the second electroluminescent layer 105 away from the base substrate 101, the third luminescent layer 107 is disposed at a side of the third metal layer 106 away from the base substrate 101, and the fourth metal layer 108 is disposed at a side of the third electroluminescent layer 107 away from the base substrate 101.

In one possible implementation mode, the first electroluminescent layer 103 may be a red electroluminescent layer, the second electroluminescent layer 105 may be a blue electroluminescent layer, and the third electroluminescent layer 107 may be a green electroluminescent layer.

In some exemplary embodiments, the first metal layer 102 is a first electrode of the first electroluminescent layer 103, the second metal layer 104 is a second electrode of the first electroluminescent layer 103 and a first electrode of the second electroluminescent layer 105, the third metal layer 106 is a second electrode of the second electroluminescent layer 105 and a first electrode of the third electroluminescent layer 107, and the fourth metal layer 108 is a second electrode of the third electroluminescent layer 107. In a possible implementation mode, a first electrode refers to an anode of an electroluminescent layer. Or, in another possible implementation mode, a first electrode refers to a cathode of an electroluminescent layer.

In some exemplary embodiments, the pixel definition layer 109 defines the first metal layer 102, the first electroluminescent layer 103, the second metal layer 104, the second electroluminescent layer 105, the third metal layer 106, the third electroluminescent layer 107, and the fourth metal layer 108 as a plurality of pixel light emitting branches. At least one of the plurality of pixel light emitting branches includes a first color light emitting element, a second color light emitting element, and a third color light emitting element. In a plurality of pixel light emitting branches of a same pixel unit, light emitting elements of a same color are connected in parallel.

In some exemplary embodiments, pixel openings spaced apart from each other are disposed in the pixel definition layer 109, and the pixel openings are configured to isolate different pixel light emitting branches from each other and define distribution positions of the pixel light emitting branches. For example, two pixel openings are schematically illustrated in FIG. 4, and the first metal layer 102, the first electroluminescent layer 103, the second metal layer 104, the second electroluminescent layer 105, the third metal layer 106, the third electroluminescent layer 107, and the fourth metal layer 108 set in one pixel opening constitute one pixel light emitting branch. For example, the first metal layer 102, the first electroluminescent layer 103, and the second metal layer 104 in the pixel light emitting branch constitute a first color light emitting element of the pixel light emitting branch, the second metal layer 104, the second electroluminescent layer 105, and the third metal layer 106 in the pixel light emitting branch constitute a second color light emitting element of the pixel light emitting branch, the third metal layer 106, the third electroluminescent layer 107, and the fourth metal layer 108 in the pixel light emitting branch constitute a third color light emitting element of the pixel light emitting branch.

Furthermore, in order to facilitate isolation of a pixel light emitting branch in case of short circuit, first metal layers 102, first electroluminescent layers 103, second metal layers 104, second electroluminescent layers 105, third metal layers 106, and third electroluminescent layers 107 of the plurality of pixel light emitting branches in the pixel unit are disposed correspondingly to pixel openings, and corresponding film layers between different pixel light emitting branches are designed to be separated from each other. A whole surface design covering a plurality of pixel light emitting branches may be adopted for the fourth metal layer 108.

In some exemplary embodiments, the pixel unit further includes a first type metal electrode, a second type metal electrode, and a third type metal electrode, wherein the first type metal electrode bridges first metal layers 102 of at least two pixel light emitting branches, the second type metal electrode bridges second metal layers 104 of at least two pixel light emitting branches, and the third type metal electrode bridges third metal layers 106 of at least two pixel light emitting branches.

As mentioned in the previous description of the pixel circuit, a first electrode of each type light emitting element may be connected to a corresponding electrode voltage. That is to say, each of the first metal layer 102, the second metal layer 104, and the third metal layer 106 may be connected to a corresponding electrode voltage.

In this way, in the display substrate according to the embodiment of the present disclosure, first metal layers 102 in at least two pixel light emitting branches can directly receive an electrical signal of a corresponding electrode voltage through the first type metal electrode. In addition, since a first color light emitting element in one or more pixel light emitting branches is of a parallel structure, a first metal layer 102 in a pixel light emitting branch without a first type metal electrode may receive a signal of the electrode voltage through a first metal layer 102 in another pixel light emitting branch connected with itself in parallel. A second metal layer 104 and a third metal layer 106 in a pixel light emitting branch are the same as the first metal layer 102, and will not be repeated here.

Therefore, for any of the first metal layer 102, the second metal layer 104, and the third metal layer 106, an electrical signal is introduced into electrode layers of at least two pixel light emitting branches of the pixel unit through a metal electrode, and the electrical signal is transmitted, by the electrode layers receiving the electrical signal, to a corresponding electrode layer where no metal electrode is disposed, so that through mutual cooperation between electrode layers in each pixel light emitting branch, a light emitting element in each pixel light emitting branch can achieve a light emitting function under drive of the electrical signal.

In this way, under a condition that any pixel light emitting branch in the pixel unit is short-circuited, the pixel light emitting branch may be isolated by cutting off electrical connections between a first metal layer 102, a second metal layer 104, and a third metal layer 106 in the pixel light emitting branch, and electrode layers in other pixel light emitting branches, and cutting off connections between the first metal layer 102, the second metal layer 104, and the third metal layer 106 in the pixel light emitting branch, and corresponding electrode voltages. Moreover, for each electrode layer in the first metal layer 102, the second metal layer 104, and the third metal layer 106, since an electrical signal is directly introduced into corresponding electrode layers in at least two pixel light emitting branches by a metal electrode, a corresponding electrode layer in at least one pixel light emitting branch remains after the short-circuited pixel light emitting branch is isolated, and the remained electrode layer can directly receive an electrical signal of a corresponding electrode voltage through a metal electrode, and the electrical signal may be transmitted, through a parallel structure between electrode layers, to a corresponding electrode layer where no metal electrode is disposed in another pixel light emitting branch. In other words, after the short-circuited pixel light emitting branch has been isolated, remaining pixel light emitting branches can still achieve a light emitting function normally.

For example, any pixel light emitting branch is short-circuited, which may be that a first metal layer 102 is short-circuited with a second metal layer 104, or may be that a second metal layer 104 is short-circuited with a third metal layer 106, or may be that a third metal layer 106 is short-circuited with a fourth metal layer 108 in the pixel light emitting branch.

Furthermore, after the short-circuited pixel light emitting branch has been isolated, light that cannot be emitted by the isolated pixel light emitting branch may be compensated by using light emitted by a remaining pixel light emitting branch in the pixel unit through optical compensation, so that the pixel unit can display normally and a product yield is ensured. For example, for the short-circuited pixel light emitting branch, brightness of a light emitting element in a pixel light emitting branch belonging to a same pixel unit as the short-circuited pixel light emitting branch may be increased, thereby compensating light of the short-circuited pixel light emitting branch. Actual compensation brightness may be measured according to experiments, which is not limited in the present disclosure.

In some exemplary embodiments, the first metal layer 102 is defined by the pixel definition layer 109 as a first first metal region included in a first pixel light emitting branch, a second first metal region included in a second pixel light emitting branch, a third first metal region included in a third pixel light emitting branch, and a fourth first metal region included in a fourth pixel light emitting branch. The second metal layer 104 is defined by the pixel definition layer 109 as a first second metal region included in the first pixel light emitting branch, a second second metal region included in the second pixel light emitting branch, a third second metal region included in the third pixel light emitting branch, and a fourth second metal region included in the fourth pixel light emitting branch. The third metal layer 106 is defined by the pixel definition layer 109 as a first third metal region included in the first pixel light emitting branch, a second third metal region included in the second pixel light emitting branch, a third third metal region included in the third pixel light emitting branch, and a fourth third metal region included in the fourth pixel light emitting branch. A first type metal electrode 1021 is located in the first metal layer 102, a second type metal electrode 1041 is located in the second metal layer 104, and a third type metal electrode 1061 is located in the third metal layer 106.

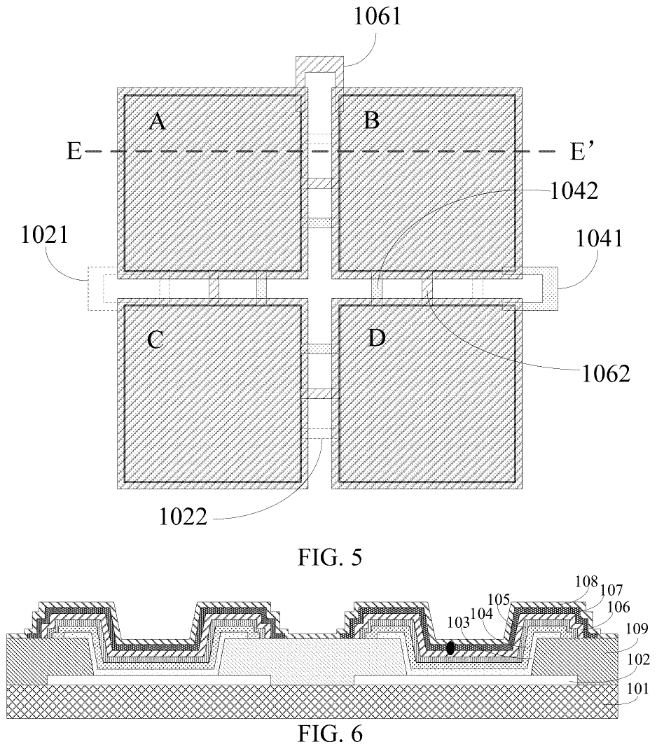

That is to say, the first metal layer 102, the first electroluminescent layer 103, the second metal layer 104, the second electroluminescent layer 105, the third metal layer 106, the third electroluminescent layer 107, and the fourth metal layer 108 are defined as four pixel light emitting branches by the pixel definition layer 109. For example, as shown in FIG. 5, in an example of FIG. 5, the four pixel light emitting branches are labeled as A, B, C, and D, respectively.

In some exemplary embodiments, referring to FIG. 5 (FIG. 4 described above may be understood as a cross-sectional view of the pixel unit schematically illustrated in FIG. 5 at a dashed line EE′), there are a plurality of metal traces 1022 in the first metal layer 102, connecting a first metal layer 102 of the pixel light emitting branch A with a first metal layer 102 of the pixel light emitting branch B, connecting a first metal layer 102 of the pixel light emitting branch C with a first metal layer 102 of the pixel light emitting branch D, connecting the first metal layer 102 of the pixel light emitting branch A with the first metal layer 102 of the pixel light emitting branch C, and connecting the first metal layer 102 of the pixel light emitting branch B with the first metal layer 102 of the pixel light emitting branch D, respectively. There are a plurality of metal traces 1042 in the second metal layer 104, connecting a second metal layer 104 of the pixel light emitting branch A with a second metal layer 104 of the pixel light emitting branch B, connecting a second metal layer 104 of the pixel light emitting branch C with a second metal layer 104 of the pixel light emitting branch D, connecting the second metal layer 104 of the pixel light emitting branch A with the second metal layer 104 of the pixel light emitting branch C, and connecting the second metal layer 104 of the pixel light emitting branch B with the second metal layer 104 of the pixel light emitting branch D, respectively. There are a plurality of metal traces 1062 in the third metal layer 106, connecting a third metal layer 106 of the pixel light emitting branch A with a third metal layer 106 of the pixel light emitting branch B, connecting a third metal layer 106 of the pixel light emitting branch C with a third metal layer 106 of the pixel light emitting branch D, connecting the third metal layer 106 of the pixel light emitting branch A with the third metal layer 106 of the pixel light emitting branch C, and connecting the third metal layer 106 of the pixel light emitting branch B with the third metal layer 106 of the pixel light emitting branch D, respectively.

In some exemplary embodiments, the first type metal electrode 1021 constitutes a first electrode potential point of the first color light emitting element, and the first type metal electrode 1021 schematically illustrated in FIG. 5 is divided into two channels to introduce electrical signals into the first metal layer 102 of the pixel light emitting branch A and the first metal layer 102 of the pixel light emitting branch C, respectively. The second type metal electrode 1041 constitutes a first electrode potential point of the second color light emitting element, and the second type metal electrode 1041 schematically illustrated in FIG. 5 is divided into two channels to introduce electrical signals into the second metal layer 104 of the pixel light emitting branch B and the second metal layer 104 of the pixel light emitting branch D, respectively. The third type metal electrode 1061 constitutes a first electrode potential point of the third color light emitting element, and the third type metal electrode 1061 schematically illustrated in FIG. 5 is divided into two channels to introduce electrical signals into the third metal layer 106 of the pixel light emitting branch A and the third metal layer 106 of the pixel light emitting branch B, respectively.

In this way, after an electrical signal enters an opening region through a metal electrode, since corresponding electrode layers between different pixel light emitting branches form a bridging structure through metal traces, a light emitting effect can be achieved by light emitting elements in a plurality of pixel light emitting branches through mutual cooperation of potentials between electrodes, and it is convenient to achieve isolation of any pixel light emitting branch subsequently. For example, taking the first metal layer 102 as an example, the first type metal electrode 1021 introduces two paths of electrical signals into the first metal layer 102 of the pixel light emitting branch A and the first metal layer 102 of the pixel light emitting branch C, respectively, and the electrical signals entering the pixel light emitting branch A and the pixel light emitting branch C are transmitted to the first metal layer 102 of the pixel light emitting branch B and the first metal layer 102 of the pixel light emitting branch D through the metal traces 1022. Processes of receiving electrical signals by the second metal layer 104 and the third metal layer 106 is the same as that of the first metal layer 102, and will not be repeated here. As may be seen, in a pixel unit structure illustrated in FIG. 4, all the pixel light emitting branches A, B, C, and D can achieve a light emitting function.

Hereinafter, with reference to FIGS. 5, 6, and 7, a technical solution in an exemplary embodiment of the present disclosure will be explained by taking a case in which a short circuit occurs in the pixel light emitting branch B and a case in which there is no short circuit in the pixel light emitting branches A, C, and D as an example.

In some exemplary embodiments, FIG. 6 is a schematic diagram of another film layer structure of a display substrate according to an embodiment of the present disclosure. In FIG. 6, a cross-sectional view of the pixel unit in FIG. 5 along an EE′ direction is schematically shown by taking a case in which a short circuit occurs in the pixel light emitting branch B as an example. Based on FIG. 6, it may be seen that there are conductive particles in the pixel light emitting branch B, which makes the pixel light emitting branch B short circuit. As may be understood with reference to FIG. 5, since electrode layers in the pixel light emitting branches A, B, C, and D form a bridging structure through metal traces, when a short circuit occurs in the pixel light emitting branch B, the pixel light emitting branches A, B, C, and D cannot emit light normally, thereby forming pixel dark spots. Here, a pixel dark dot is illustrated by a black oval dot in FIG. 6.

In order to repair a dark spot of a pixel unit of the display substrate, a metal trace 1022 between the first metal layer 102 in the short-circuited pixel light emitting branch B and a first metal layer 102 in another pixel light emitting branch may be cut off, a metal trace 1042 between the second metal layer 104 in the short-circuited pixel light emitting branch B and a second metal layer 104 in another pixel light emitting branch may be cut off, a metal trace 1062 between the third metal layer 106 in the short-circuited pixel light emitting branch B and a third metal layer 106 in another pixel light emitting branch may be cut off, and metal electrodes disposed on the first metal layer 102, the second metal layer 104, and the third metal layer 106 in the short-circuited pixel light emitting branch B may be cut off, in this way, it may be ensured that the pixel light emitting branch B is isolated and that the pixel light emitting branch A, C, and D can still emit light normally.

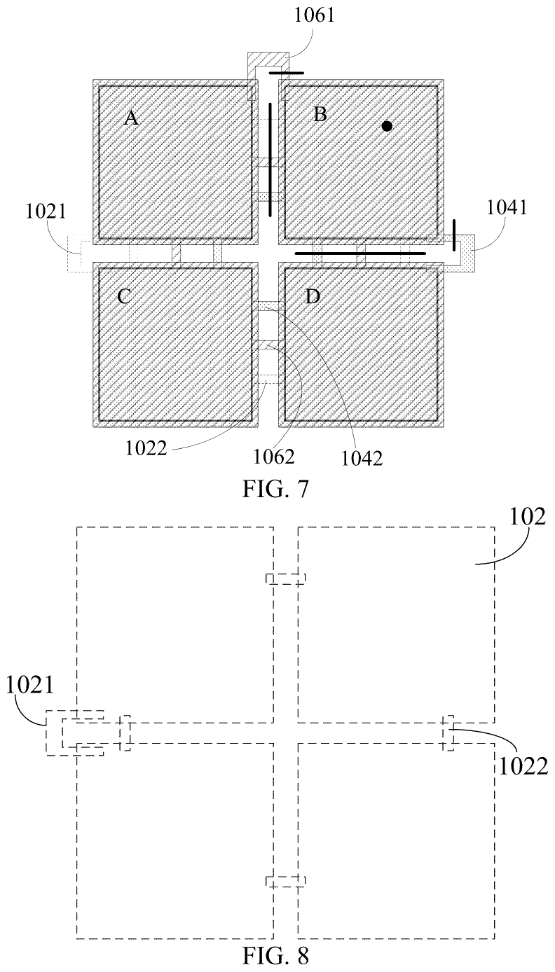

In some exemplary embodiments, referring to FIG. 7, FIG. 7 illustrates a schematic diagram of a solution of performing dark spot repair on the pixel unit in a case that the pixel light emitting branch B is short-circuited. For example, by laser cutting, a metal trace 1022, a metal trace 1042, and a metal trace 1062 connected between the pixel light emitting branch B and the pixel light emitting branch A may be cut off, a metal trace 1022, a metal trace 1042, and a metal trace 1062 connected between the pixel light emitting branch B and the pixel light emitting branch D may be cut off, and the second type metal electrode 1041 and the third type metal electrode 1061 directly connected to the pixel light emitting branch B may be cut off. Herein, in FIG. 7, a corresponding metal trace is cut off which is indicated by a black straight line, and a pixel dark spot is indicated by a black dot.

After the above laser cutting is completed, the pixel light emitting branch B is isolated and does not emit light any more. The first type metal electrode 1021 is not cut off, and it can still introduce electrical signals into first metal layers 102 of the pixel light emitting branch A and the pixel light emitting branch C, respectively, and an electrical signal is transmitted by the first metal layer 102 of the pixel light emitting branch C to the first metal layer 102 of the pixel light emitting branch D through a metal trace 1022. The second metal layer 104 of the pixel light emitting branch D can still receive an electrical signal through the second type metal electrode 1041, and transmit the electrical signal to second metal layers 104 in the pixel light emitting branches C and A through metal traces 1042. The third metal layer 106 of the pixel light emitting branch A can still receive an electrical signal through the third type metal electrode 1061, and transmit the electrical signal to third metal layers 106 in the pixel light emitting branches C and D through metal traces 1062. Therefore, the pixel light emitting branches A, C, and D can still work normally.

Furthermore, after the pixel light emitting branch B is isolated, light that cannot be emitted by the pixel light emitting branch B may be optically compensated through the pixel light emitting branches A, C, and D, so as to ensure that the pixel unit can normally display. For example, optical compensation may be achieved by increasing luminous brightness of the pixel luminous branches A, C, and D to ensure that a corresponding pixel unit can normally display, thereby improving a yield of the display substrate.

Similar to the above-mentioned process of performing dark spot repair on the pixel light emitting branch B, when any of the pixel light emitting branches A, C, and D is short-circuited, dark spot repair can be achieved based on a same principle.

In order to facilitate understanding of the film layer structure of the pixel unit in the display substrate according to the embodiment, FIGS. 8 to 12 provide schematic diagrams of several different structures of the pixel unit in a process of preparing the display substrate according to the exemplary embodiment of the present disclosure.

In some exemplary embodiments, as shown in FIG. 8, FIG. 8 illustrates a structure of a first metal layer 102, and a first type metal electrode 1021 and a metal trace 1022 included in the first metal layer 102. As may be seen from FIG. 8, first metal layers 102 of four pixel light emitting branches are designed to be separated from each other. Here, a structure of a first metal layer 102 of each pixel light emitting branch is schematic, and a patterning design may be performed on the first metal layer 102 of each pixel light emitting branch in a preparation process based on actual needs.

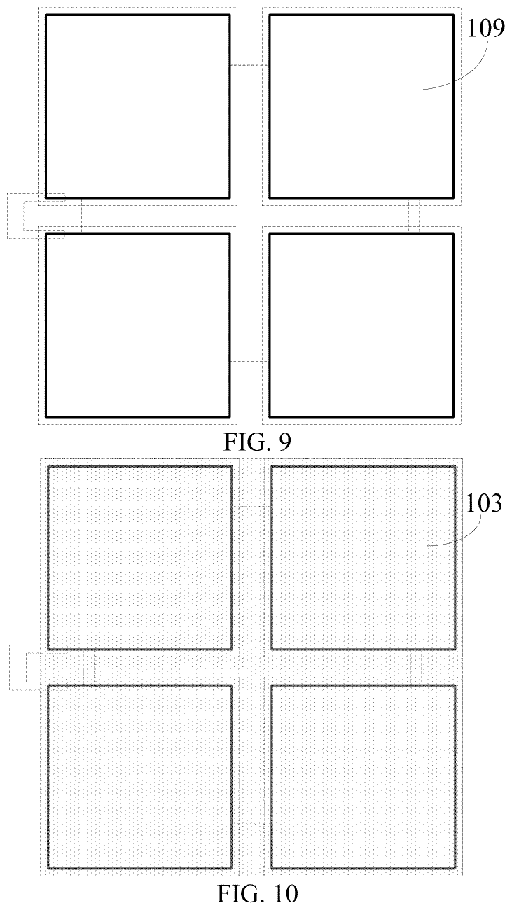

In some exemplary embodiments, as shown in FIG. 9, FIG. 9 illustrates a structure of a pixel definition layer 109, based on FIG. 8. It may be seen from FIG. 9 that the pixel definition layer 109 provides four pixel openings in the pixel unit and divides the pixel unit into four light emitting regions. In one possible implementation mode, the four regions are equal in size.

In some exemplary embodiments, as shown in FIG. 10, FIG. 10 illustrates a structure of a first electroluminescent layer 103 based on FIG. 9.

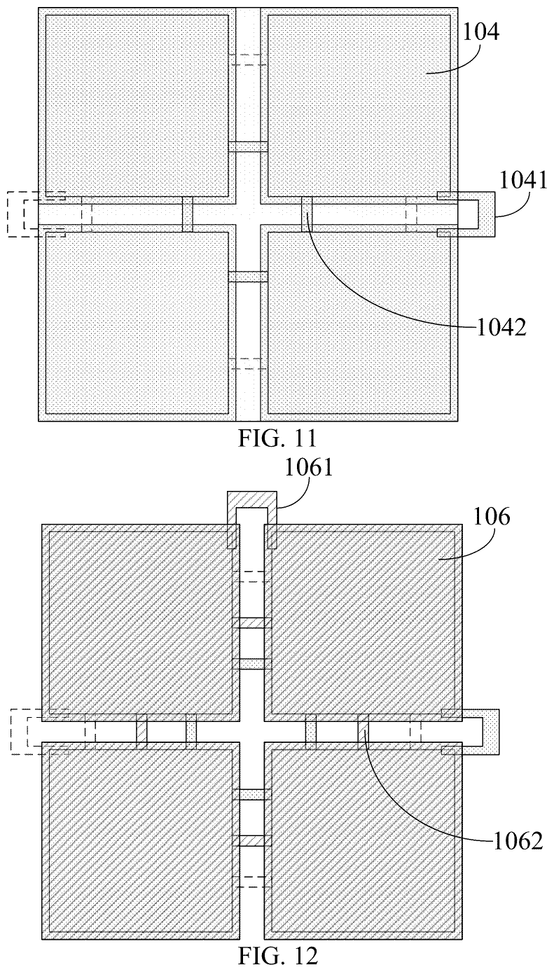

In some exemplary embodiments, as shown in FIG. 11, FIG. 11 illustrates a second type metal electrode 1041 and a metal trace 1042 included in a second metal layer 104, and a structure of the second metal layer 104, based on FIG. 10.

In some exemplary embodiments, as shown in FIG. 12, FIG. 12 illustrates a second type metal electrode 1041 and a metal trace 1042 included in a second metal layer 104, a third type metal electrode 1061 and a metal trace 1062 included in a third metal layer 106, a structure of the second metal layer 104, and a structure of the third metal layer 106, based on FIG. 9. Based on FIG. 12, it may be seen that first metal layers 102, second metal layers 104, and third metal layers 106 within different light emitting regions are separated from each other in a grid shape under limitation of the pixel openings.

The display substrate according to the above-mentioned exemplary embodiment can achieve dark spot repair in a case where any pixel light emitting branch in the pixel unit is short-circuited.

When both the pixel light emitting branch B and the pixel light emitting branch C illustrated in FIG. 5 are short-circuited, all metal traces 1022, 1042, and 1062 disposed in the pixel unit may be cut off. In this case, the second metal layer 104 of the pixel light emitting branch A cannot receive an electrical signal, the first metal layer 102 and the third metal layer 106 of the pixel light emitting branch D cannot receive an electrical signal, and the pixel light emitting branches A and D cannot emit light normally, and a dark spot repair effect cannot be achieved.

Therefore, in order to achieve dark spot repair in a display substrate when any plurality of pixel light emitting branches in a pixel unit are short-circuited, another display substrate is provided in an exemplary embodiment of the present disclosure. The display substrate includes a pixel circuit in one or more exemplary embodiments mentioned above. The pixel circuit includes a plurality of pixel units, and the pixel circuit may include four pixel light emitting branches. The four pixel light emitting branches include a first pixel light emitting branch, a second pixel light emitting branch, a third pixel light emitting branch, and a fourth pixel light emitting branch. Herein, the pixel unit includes two first type metal electrodes, wherein one first type metal electrode bridges first electrodes of first color light emitting elements in the first pixel light emitting branch and the second pixel light emitting branch, and the other first type metal electrode bridges first electrodes of first color light emitting elements in the third pixel light emitting branch and the fourth pixel light emitting branch. The pixel unit includes two second type metal electrodes, wherein one second type metal electrode bridges first electrodes of second color light emitting elements in the second pixel light emitting branch and the fourth pixel light emitting branch, and the other second type metal electrode bridges first electrodes of second color light emitting elements in the first pixel light emitting branch and the third pixel light emitting branch. The pixel unit includes two third type metal electrodes, wherein one third type metal electrodes bridges first electrodes of third color light emitting elements in the first pixel light emitting branch and the third pixel light emitting branch, and the other third type metal electrode bridges first electrodes of third color light emitting element in the second pixel light emitting branch and the fourth pixel light emitting branch.

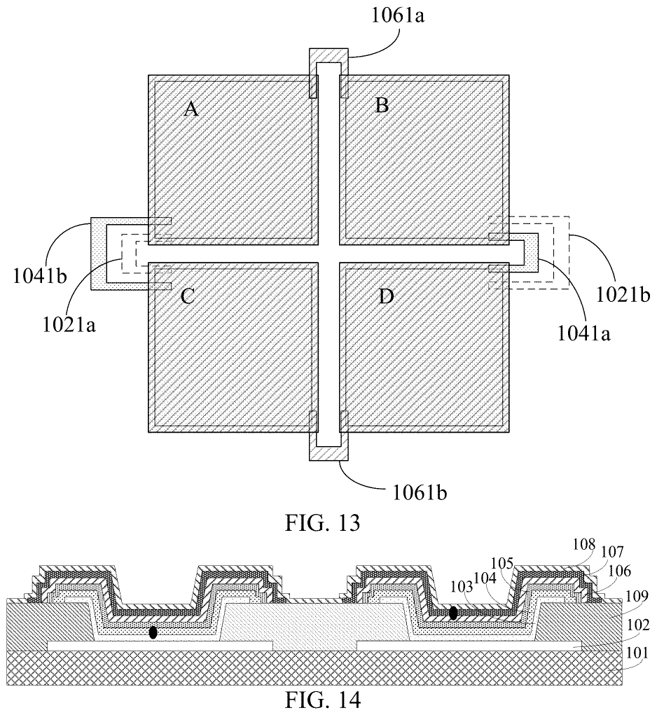

In some exemplary embodiments, as shown in conjunction with FIGS. 5 and 13, in FIG. 13, a corresponding metal electrode is added on an opposite side of each metal electrode on a basis of several metal electrodes shown in FIG. 5. As shown in FIG. 13, the pixel unit may include two first type metal electrodes 1021, two second type metal electrodes 1041, and two third type metal electrodes 1061.

The two first type metal electrodes 1021 may include one first type metal electrode 1021a and another first type metal electrode 1021b, and the first type metal electrode 1021b is disposed at an opposite side of the first type metal electrode 1021a. Electrical signals are introduced into the first metal layer 102 of the pixel light emitting branch A and the first metal layer 102 of the pixel light emitting branch C by the first type metal electrode 1021a in two channels, respectively. Electrical signals are introduced into the first metal layer 102 of the pixel light emitting branch B and the first metal layer 102 of the pixel light emitting branch D by the first type metal electrode 1021b in two channels, respectively.

The two second type metal electrodes 1041 may include one second type metal electrode 1041a and another second type metal electrode 1041b, and the second type metal electrode 1041b is disposed at an opposite side of the second type metal electrode 1041a. Electrical signals are introduced into the second metal layer 104 of the pixel light emitting branch B and the second metal layer of the pixel light emitting branch D by the second type metal electrode 1041a in two channels, respectively. Electrical signals are introduced into the second metal layer 104 of the pixel light emitting branch A and the second metal layer of the pixel light emitting branch C by the second type metal electrode 1041b in two channels, respectively.

The two third type metal electrodes 1061 may include one third type metal electrode 1061a and another third type metal electrode 1061b, and the third type metal electrode 1061b is disposed at an opposite side of the third type metal electrode 1061a. Electrical signals are introduced into the third metal layer 106 of the pixel light emitting branch A and the third metal layer 106 of the pixel light emitting branch B by the third type metal electrode 1061a in two channels, respectively. Electrical signals are introduced into the third metal layer 106 of the pixel light emitting branch C and the third metal layer 106 of the pixel light emitting branch D by the third type metal electrode 1061b in two channels, respectively.

Here, in FIG. 13, illustration is made by taking a case in which the first type metal electrode 1021a corresponds to the first type metal electrode 1021 in the pixel unit provided by FIG. 5, the second type metal electrode 1041a corresponds to the second type metal electrode 1041 in the pixel unit provided by FIG. 5, and the third type metal electrode 1061a corresponds to the third type metal electrode 1061 in the pixel unit provided by FIG. 5 as an example.

Hereinafter, in conjunction with FIGS. 13, 14, and 15, a process of performing dark spot repair on the display substrate according to the exemplary embodiment of the present disclosure will be described by taking a case where the pixel light emitting branch B and the pixel light emitting branch C are short-circuited as an example. FIG. 14 is a schematic diagram showing a film layer structure of the pixel unit shown in FIG. 13 by taking a case where the pixel light emitting branch B and the pixel light emitting branch C are short-circuited as an example, and it may be seen from FIG. 14 that there are conductive particles in both the pixel light emitting branch C and the pixel light emitting branch B, so that the two pixel light emitting branches are short-circuited.

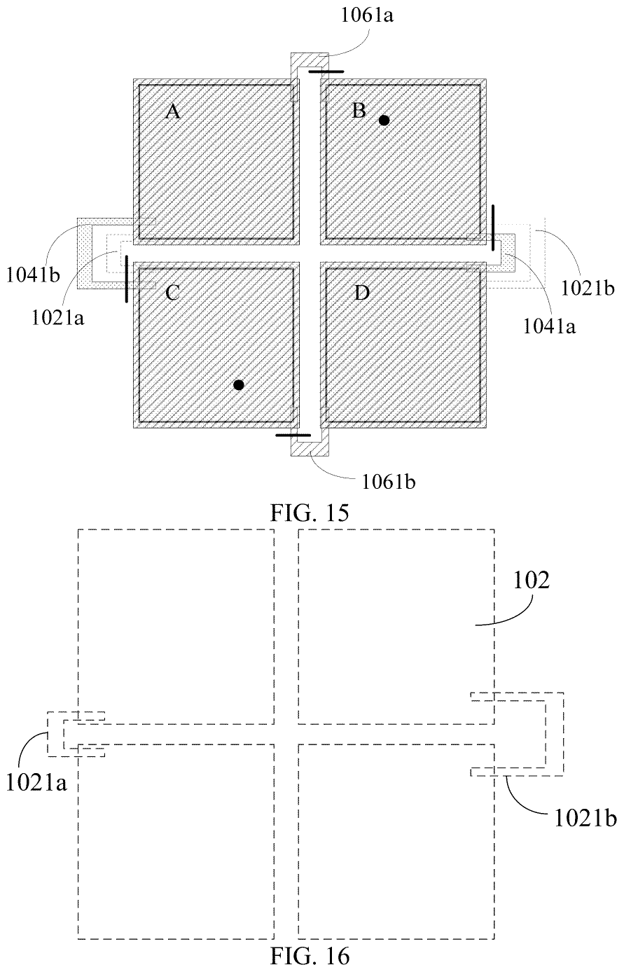

In some exemplary embodiments, referring to FIG. 15, FIG. 15 illustrates a schematic diagram of a solution of performing dark spot repair on the pixel unit in a case in which the pixel light emitting branch B and the pixel light emitting branch C are short-circuited. For example, in a case in which the pixel light emitting branch B and the pixel light emitting branch C are short-circuited, by laser cutting, the third type metal electrode 1061a, the second type metal electrode 1041a, and the first type metal electrode 1021b which are connected with the pixel light emitting branch B may be cut off, and the first type metal electrode 1021a, the second type metal electrode 1041b, and the third type metal electrode 1061b which are connected with the pixel light emitting branch C may be cut off, thereby achieving isolation of the pixel light emitting branches B and C, and ensuring the pixel light emitting branches A and D can work normally.

Similar to the above-mentioned process of performing dark spot repair on the pixel light emitting branch B and the pixel light emitting branch C, in a case that any two or three of the pixel light emitting branches A, B, C, and D are short-circuited, dark spot repair can be achieved based on a same principle.

In order to facilitate understanding of a film layer structure of the pixel unit in the display substrate according to the embodiment, FIGS. 16 to 19 provide schematic diagrams of several different structures of the pixel unit in the process of preparing the display substrate according to the exemplary embodiment of the present disclosure.

In some exemplary embodiments, as shown in FIG. 16, FIG. 16 illustrates two first type metal electrodes 1021 (which may include one first type metal electrode 1021a and another first type metal electrode 1021b) included in a first metal layer 102, and a structure of the first metal layer 102. The first metal layer 102 may further include a metal trace 1022 (not shown).

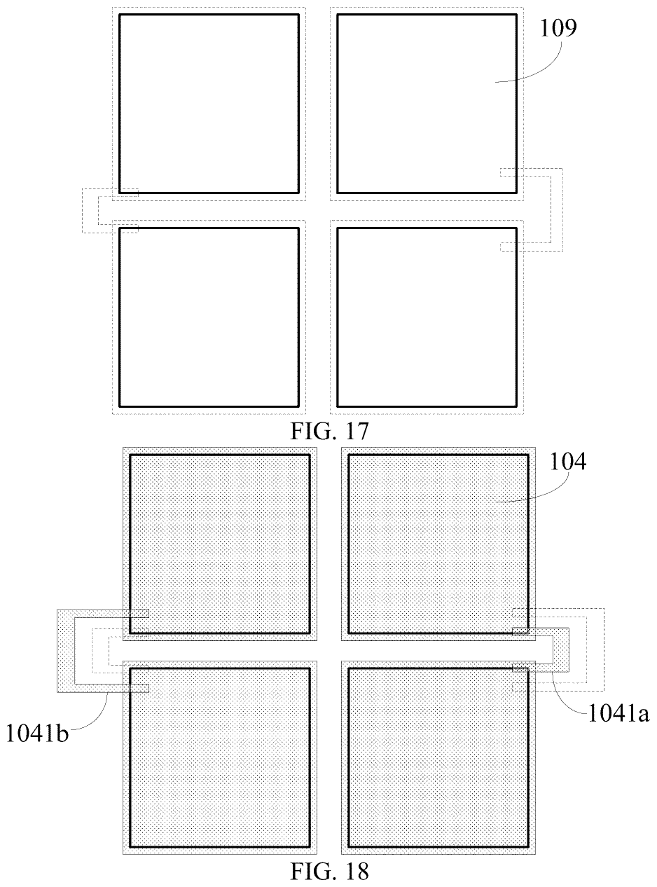

In some exemplary embodiments, as shown in FIG. 17, FIG. 17 illustrates a structure of a pixel definition layer 109 based on FIG. 16.

In some exemplary embodiments, as shown in FIG. 18, FIG. 18 illustrates two second type metal electrodes 1041 (which may include one second type metal electrode 1041a and another second type metal electrode 1041b) included in a second metal layer 104, and a structure of the second metal layer 104, based on FIG. 17. The second metal layer 104 may further include a metal trace 1042 (not shown).

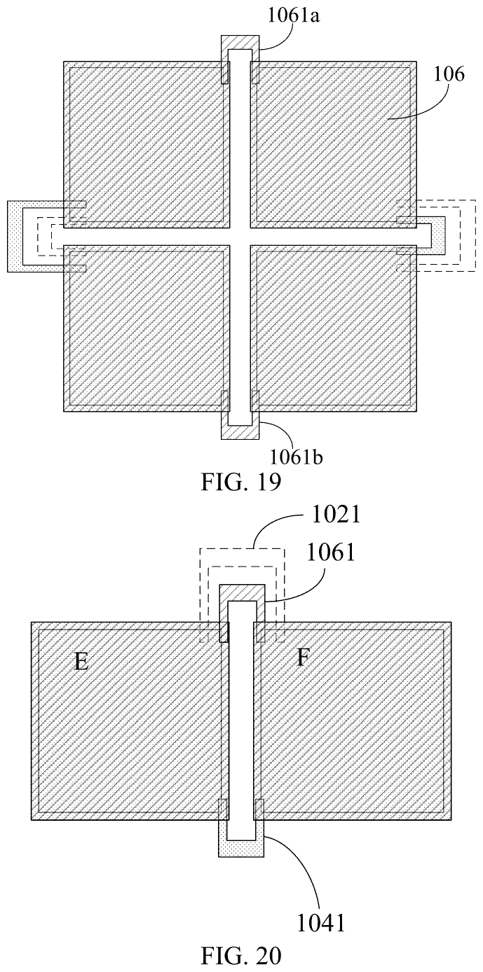

In some exemplary embodiments, as shown in FIG. 19, FIG. 19 illustrates two third type metal electrodes 1061 (which may include one third type metal electrode 1061a and another third type metal electrode 1061b) included in a third metal layer 106, and a structure of the third metal layer 106, based on FIG. 18. The third metal layer 106 may further include a metal trace 1062 (not shown).

In some exemplary embodiments, referring to FIG. 20, in the display substrate according to the exemplary embodiment of the present disclosure, the first metal layer 102, the first electroluminescent layer 103, the second metal layer 104, the second electroluminescent layer 105, the third metal layer 106, the third electroluminescent layer 107, and the fourth metal layer 108 may be defined as two pixel light emitting branches by the pixel definition layer 109. Herein, the two pixel light emitting branches are labeled as E and F, respectively, in FIG. 20.

In some exemplary embodiments, the first type metal electrode 1021 bridges a first metal layer 102 of a pixel light emitting branch E and a first metal layer 102 of a pixel light emitting branch F, the second type metal electrode 1041 bridges a second metal layer 104 of the pixel light emitting branch E and a second metal layer 104 of the pixel light emitting branch F, and the third type metal electrode 1061 bridges a third metal layer 106 of the pixel light emitting branch E and a third metal layer 106 of the pixel light emitting branch F.

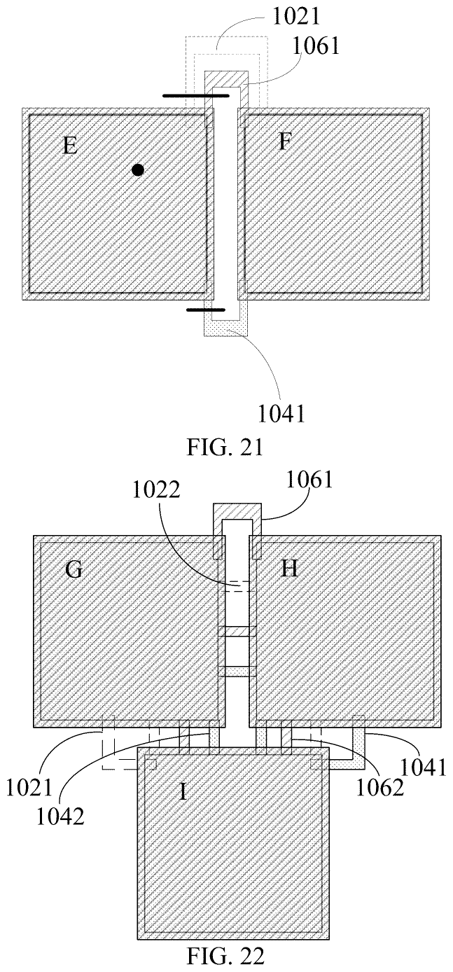

In some exemplary embodiments, referring to FIG. 21, FIG. 21 illustrates a schematic diagram of a solution of performing dark spot repair on the pixel unit in which the pixel light emitting branch E is short-circuited. For example, for the display substrate according to the embodiment, in a case that the pixel light emitting branch E is short-circuited, dark spot repair may be achieved by laser cutting a first type metal electrode 1021, a second type metal electrode 1041, and a third type metal electrode 1061 shown in FIG. 21.

In some exemplary embodiments, referring to FIG. 22, in an exemplary embodiment of the present disclosure, the first metal layer 102, the first electroluminescent layer 103, the second metal layer 104, the second electroluminescent layer 105, the third metal layer 106, the third electroluminescent layer 107, and the fourth metal layer 108 may be defined as three pixel light emitting branches by the pixel definition layer 109. Herein, in FIG. 22, the three pixel light emitting branches are labeled as G, H, and I, respectively.

In some exemplary embodiments, there are a plurality of metal traces 1022 in the first metal layer 102, which connect a first metal layer 102 of the pixel light emitting branch G with a first metal layer 102 of a pixel light emitting branch H, connect the first metal layer 102 of the pixel light emitting branch H with a first metal layer 102 of a pixel light emitting branch I, and connect the first metal layer 102 of the pixel light emitting branch I with the first metal layer 102 of the pixel light emitting branch G, respectively. There are a plurality of metal traces 1042 in the second metal layer 104, which connect a second metal layer 104 of the pixel light emitting branch G with a second metal layer 104 of the pixel light emitting branch H, connect the second metal layer 104 of the pixel light emitting branch H with a second metal layer 104 of the pixel light emitting branch I, and connect the second metal layer 104 of the pixel light emitting branch I with the second metal layer 104 of the pixel light emitting branch G, respectively. There are a plurality of metal traces 1062 in the third metal layer 106, which connect a third metal layer 106 of the pixel light emitting branch G with a third metal layer 106 of the pixel light emitting branch H, connect the third metal layer 106 of the pixel light emitting branch H with a third metal layer 106 of the pixel light emitting branch I, and connect the third metal layer 106 of the pixel light emitting branch I with the third metal layer 106 of the pixel light emitting branch G, respectively.

In some exemplary embodiments, the first type metal electrode 1021 bridges the first metal layer 102 of the pixel light emitting branch G and the first metal layer 102 of the pixel light emitting branch I, the second type metal electrode 1041 bridges the second metal layer 104 of the pixel light emitting branch H and the second metal layer 104 of the pixel light emitting branch I, and the third type metal electrode 1061 bridges the third metal layer 106 of the pixel light emitting branch G and the third metal layer 106 of the pixel light emitting branch H.

As may be seen, in a pixel unit illustrated in FIG. 22, each electrode layer in each pixel light emitting branch can directly receive an electrical signal of a corresponding first electrode through a metal electrode or indirectly receive an electrical signal of a corresponding electrode voltage through a metal trace, so that each of the pixel light emitting branches G, H, and I can achieve a light emitting function.

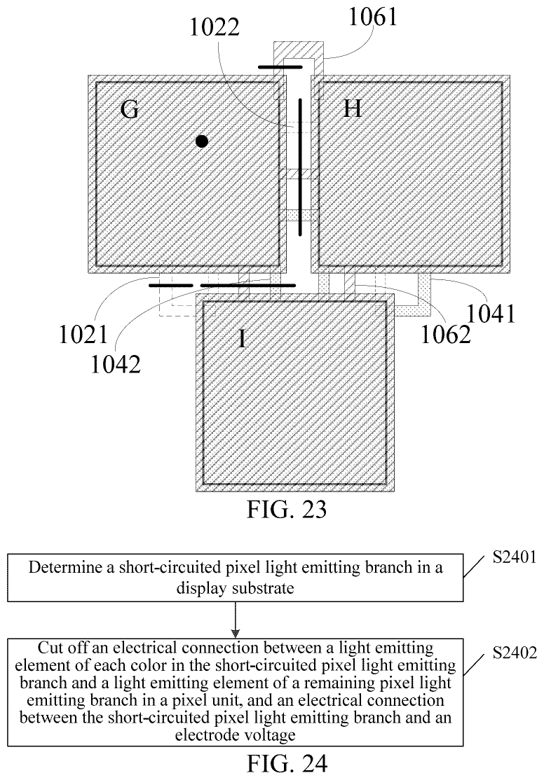

In some exemplary embodiments, referring to FIG. 23, FIG. 23 illustrates a schematic diagram of a solution of performing dark spot repair on the pixel unit in a case that the pixel light emitting branch G is short-circuited. For example, in the display substrate according to the embodiment, in a case that the pixel light emitting branch G is short-circuited, the pixel light emitting branch G may be isolated by cutting off a metal trace disposed between the pixel light emitting branch G and the pixel light emitting branch H, and a metal trace disposed between the pixel light emitting branch G and the pixel light emitting branch I, and cutting off a first type metal electrode 1021 and a third type metal electrode 1061 which are connected with the pixel light emitting branch G, and it is ensured that the pixel light emitting branches H and I emit light normally, so that dark spot repair is achieved.

In this way, in the display substrate according to the embodiment of the present disclosure, a pixel unit is divided into a plurality of pixel light emitting branches according to a quantity of electrodes, a design in which a pixel light emitting branch may be repaired is provided, so that different pixel light emitting branches in the pixel unit can interact to achieve light emission, and at the same time, a short-circuited pixel light emitting branch may be isolated by laser repair to form a dark spot repair effect, thereby improving a product yield and providing technical support for ultra-high PPI products.

The present disclosure also provides a dark spot repair method applied to any of the above-mentioned display substrates. As shown in FIG. 24, the method includes following acts. In act S2401, a short-circuited pixel light emitting branch in the display substrate is determined.

Herein, any combination of following situations may occur in the short-circuited pixel light emitting branch: a first metal layer 102 is short-circuited with a second metal layer 104, the second metal layer 104 is short-circuited with a third metal layer 106, and the third metal layer 106 is short-circuited with a fourth metal layer 108.

In act S2402, an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage are cut off.

Herein, the electrode voltage includes an electrode voltage connected to the first metal layer 102, an electrode voltage connected to the second metal layer 104, and an electrode voltage connected to the third metal layer 106.

For example, when the display substrate according to any of the above-mentioned embodiments of the present disclosure is applied, by cutting off an electrical connection between a short-circuited pixel light emitting branch and a remaining pixel light emitting branch in a pixel unit, and cutting off an electrical connection between the short-circuited pixel light emitting branch and an electrode voltage, the pixel light emitting branch may be isolated, so as to ensure that the remaining pixel light emitting branches in the pixel unit can work normally, and a dark spot repair effect can be achieved.

The above-mentioned dark spot repair method is described below with several examples.

In some exemplary embodiments, in a case that there is no metal trace between the short-circuited pixel light emitting branch and other pixel light emitting branches, all metal traces disposed between the short-circuited pixel light emitting branch and the other pixel light emitting branches may be cut off. In a case that a first type metal electrode 1021, a second type metal electrode 1041, or a third type metal electrode 1061 is connected with any electrode layer in the short-circuited pixel light emitting branch, these metal electrodes may be cut off.

After the above-mentioned operations are completed, the short-circuited pixel light emitting branches may be isolated, so as to ensure that a remaining pixel light emitting branch may work normally, and dark spot repair may be achieved. An actual repair process may be referred to the previous description about FIGS. 5, 6, and 7.

In some other exemplary embodiments, in a case that there is no metal trace between the short-circuited pixel light emitting branch and other pixel light emitting branches, by cutting off a first type metal electrode 1021, a second type metal electrode 1041, and a third type metal electrode 1061 which are connected with an electrode layer in the short-circuited pixel light emitting branch, the short-circuited pixel light emitting branch may be isolated, so as to ensure that a remaining pixel light emitting branch may work normally, and dark spot repair may be achieved. An actual repair process may be referred to the previous description about FIGS. 13, 14, and 15.

Relational terms such as first and second are used herein only to distinguish one entity or operation from another entity or operation without necessarily requiring or implying any such actual relationship or order between these entities or operations. Moreover, the terms “include”, “contain” or any other variations thereof are intended to cover a non-exclusive inclusion, so that a process, method, article, or device that includes a series of elements includes not only those elements but also other elements which are not expressly listed, or further includes elements inherent to such a process, method, article, or device. An element defined by a statement “include one . . . ” does not exclude presence of additional identical elements in the process, method, article or device that includes the element, without more limitations.

The above description is only exemplary embodiments of the present disclosure and is not intended to limit the scope of protection of the present disclosure. Any modification, equivalent substitution, improvement, and the like made within the spirit and principles of the present disclosure are included within the scope of protection of the present disclosure.

1. A pixel circuit, comprising:
a plurality of pixel units, wherein a pixel unit of the plurality of pixel units comprises at least two pixel light emitting branches;
a pixel light emitting branch of the at least two pixel light emitting branches comprises at least two of a first color light emitting element, a second color light emitting element, and a third color light emitting element; in each pixel light emitting branch of a same pixel unit, light emitting elements of a same color are connected in parallel;
the pixel unit further comprises a first type metal electrode, a second type metal electrode, and a third type metal electrode, wherein the first type metal electrode is used to be connected to an electrode voltage of the first color light emitting element, the second type metal electrode is used to be connected to an electrode voltage of the second color light emitting element, and the third type metal electrode is used to be connected to an electrode voltage of the third color light emitting element;
the first type metal electrode bridges first electrodes of first color light emitting elements of at least two pixel light emitting branches, the second type metal electrode bridges first electrodes of second color light emitting elements of at least two pixel light emitting branches, and the third type metal electrode bridges first electrodes of third color light emitting elements of at least two pixel light emitting branches.

2. The pixel circuit according to claim 1, wherein the pixel unit comprises two pixel light emitting branches;
the first type metal electrode bridges a first electrode of a first color light emitting element of each of the two pixel light emitting branches, the second type metal electrode bridges a first electrode of a second color light emitting element of each of the two pixel light emitting branches, and the third type metal electrode bridges a first electrode of a third color light emitting element of each of the two pixel light emitting branches.

3. The pixel circuit according to claim 1, wherein the pixel unit comprises three pixel light emitting branches;
the first type metal electrode bridges first electrodes of first color light emitting elements of at least two of the three pixel light emitting branches, the second type metal electrode bridges first electrodes of second color light emitting elements of at least two of the three pixel light emitting branches, and the third type metal electrode bridges first electrodes of third color light emitting elements of at least two of the three pixel light emitting branches.

4. The pixel circuit according to claim 1, wherein the pixel circuit comprises four pixel light emitting branches;
first electrodes of light emitting elements of a same color in the four pixel light emitting branches are connected with each other through metal traces;
the first type metal electrode bridges first electrodes of first color light emitting elements of two of the four pixel light emitting branches, the second type metal electrode bridges first electrodes of second color light emitting elements of two of the four pixel light emitting branches, and the third type metal electrode bridges first electrodes of third color light emitting elements of two of the four pixel light emitting branches.

5. The pixel circuit according to claim 1, wherein the pixel circuit comprises four pixel light emitting branches;
the first type metal electrode bridges a first electrode of a first color light emitting element of each of the four pixel light emitting branches, the second type metal electrode bridges a first electrode of a second color light emitting element of each of the four pixel light emitting branches, and the third type metal electrode bridges a first electrode of a third color light emitting element of each of the four pixel light emitting branches.

6. The pixel circuit according to claim 5, wherein the four pixel light emitting branches comprise a first pixel light emitting branch, a second pixel light emitting branch, a third pixel light emitting branch, and a fourth pixel light emitting branch;
the pixel unit comprises two first type metal electrodes, wherein one first type metal electrode bridges first electrodes of first color light emitting elements in the first pixel light emitting branch and the second pixel light emitting branch, and the other first type metal electrode bridges first electrodes of first color light emitting elements in the third pixel light emitting branch and the fourth pixel light emitting branch; the pixel unit comprises two second type metal electrodes, wherein one second type metal electrode bridges first electrodes of second color light emitting elements in the second pixel light emitting branch and the fourth pixel light emitting branch, and the other second type metal electrode bridges first electrodes of second color light emitting elements in the first pixel light emitting branch and the third pixel light emitting branch; the pixel unit comprises two third type metal electrodes, wherein one third type metal electrode bridges first electrodes of third color light emitting elements in the first pixel light emitting branch and the third pixel light emitting branch, and the other third type metal electrode bridges first electrodes of third color light emitting elements in the second pixel light emitting branch and the fourth pixel light emitting branch.

7. The pixel circuit according to claim 1, wherein a first color light emitting element, a second color light emitting element, and a third color light emitting element in a same pixel light emitting branch are stacked and arranged.

8. A display substrate, comprising: a base substrate and at least two pixel units disposed on the base substrate; wherein
a pixel unit of the at least two pixel units comprises a first metal layer, a first electroluminescent layer, a second metal layer, a second electroluminescent layer, a third metal layer, a third electroluminescent layer, a fourth metal layer, and a pixel definition layer;
the first metal layer is disposed on the base substrate, the first electroluminescent layer is disposed at a side of the first metal layer away from the base substrate, the second metal layer is disposed at a side of the first electroluminescent layer away from the base substrate, the second electroluminescent layer is disposed at a side of the second metal layer away from the base substrate, the third metal layer is disposed at a side of the second electroluminescent layer away from the base substrate, the third electroluminescent layer is disposed at a side of the third metal layer away from the base substrate, and the fourth metal layer is disposed at a side of the third electroluminescent layer away from the base substrate;
the first metal layer, the first electroluminescent layer, the second metal layer, the second electroluminescent layer, the third metal layer, the third electroluminescent layer, and the fourth metal layer are defined as a plurality of pixel light emitting branches by the pixel definition layer; a pixel light emitting branch of the plurality of pixel light emitting branches comprises a first color light emitting element, a second color light emitting element, and a third color light emitting element; in each pixel light emitting branch of a same pixel unit, light emitting elements of a same color are connected in parallel;
the pixel unit further comprises a first type metal electrode, a second type metal electrode, and a third type metal electrode, wherein the first type metal electrode bridges first metal layers of at least two pixel light emitting branches, the second type metal electrode bridges second metal layers of at least two pixel light emitting branches, and the third type metal electrode bridges third metal layers of at least two pixel light emitting branches.

9. The display substrate according to claim 8, wherein the first metal layer, the first electroluminescent layer, the second metal layer, the second electroluminescent layer, the third metal layer, the third electroluminescent layer, and the fourth metal layer are defined as two pixel light emitting branches by the pixel definition layer; the first type metal electrode is located in the first metal layer; the second type metal electrode is located in the second metal layer; and the third type metal electrode is located in the third metal layer;
the first type metal electrode bridges a first metal layer of each of the two pixel light emitting branches; the second type metal electrode bridges a second metal layer of each of the two pixel light emitting branches; and the third type metal electrode bridges a third metal layer of each of the two pixel light emitting branches.

10. The display substrate according to claim 8, wherein the first metal layer, the first electroluminescent layer, the second metal layer, the second electroluminescent layer, the third metal layer, the third electroluminescent layer, and the fourth metal layer are defined as three pixel light emitting branches by the pixel definition layer; the first type metal electrode is located in the first metal layer; the second type metal electrode is located in the second metal layer; and the third type metal electrode is located in the third metal layer;
first metal layers in the three pixel light emitting branches are connected with each other through metal traces; second metal layers in the three pixel light emitting branches are connected with each other through metal traces; and third metal layers in the three pixel light emitting branches are connected with each other through metal traces;
the first type metal electrode bridges first metal layers of two of the three pixel light emitting branches; the second type metal electrode bridges second metal layers of two of the three pixel light emitting branches; and the third type metal electrode bridges third metal layers of two of the three pixel light emitting branches.

11. The display substrate according to claim 8, wherein the first metal layer, the first electroluminescent layer, the second metal layer, the second electroluminescent layer, the third metal layer, the third electroluminescent layer, and the fourth metal layer are defined as four pixel light emitting branches by the pixel definition layer; the first type metal electrode is located in the first metal layer; the second type metal electrode is located in the second metal layer; and the third type metal electrode is located in the third metal layer;
first metal layers in the four pixel light emitting branches are connected with each other through metal traces; second metal layers in the four pixel light emitting branches are connected with each other through metal traces; and third metal layers in the four pixel light emitting branches are connected with each other through metal traces;
the first type metal electrode bridges first metal layers of at least two of the four pixel light emitting branches; the second type metal electrode bridges second metal layers of at least two of the four pixel light emitting branches; and the third type metal electrode bridges third metal layers of at least two of the four pixel light emitting branches.

12. The display substrate according to claim 11, wherein the first metal layer is defined by the pixel definition layer as a first first metal region comprised in a first pixel light emitting branch, a second first metal region comprised in a second pixel light emitting branch, a third first metal region comprised in a third pixel light emitting branch, and a fourth first metal region comprised in a fourth pixel light emitting branch; the second metal layer is defined by the pixel definition layer as a first second metal region comprised in the first pixel light emitting branch, a second second metal region comprised in the second pixel light emitting branch, a third second metal region comprised in the third pixel light emitting branch, and a fourth second metal region comprised in the fourth pixel light emitting branch; the third metal layer is defined by the pixel definition layer as a first third metal region comprised in the first pixel light emitting branch, a second third metal region comprised in the second pixel light emitting branch, a third third metal region comprised in the third pixel light emitting branch, and a fourth third metal region comprised in the fourth pixel light emitting branch; the first type metal electrode is located in the first metal layer, the second type metal electrode is located in the second metal layer, and the third type metal electrode is located in the third metal layer;
the first first metal region and the second first metal region are connected through a metal trace, the second first metal region and the third first metal region are connected through a metal trace, the third first metal region and the fourth first metal region are connected through a metal trace, and the fourth first metal region and the first first metal region are connected through a metal trace; the first second metal region and the second second metal region are connected through a metal trace, the second second metal region and the third second metal region are connected through a metal trace, the third second metal region and the fourth second metal region are connected through a metal trace, and the fourth second metal region and the first second metal region are connected through a metal trace; the first third metal region and the second third metal region are connected through a metal trace, the second third metal region and the third third metal region are connected through a metal trace, the third third metal region and the fourth third metal region are connected through a metal trace, and the fourth third metal region and the first third metal region are connected through a metal trace;
the first type metal electrode bridges the first first metal region and the second first metal region, the second type metal electrode bridges the second second metal region and the fourth second metal region, and the third type metal electrode bridges the first third metal region and the third third metal region.

13. The display substrate according to claim 11, wherein the first metal layer is defined by the pixel definition layer as a first first metal region comprised in a first pixel light emitting branch, a second first metal region comprised in a second pixel light emitting branch, a third first metal region comprised in a third pixel light emitting branch, and a fourth first metal region comprised in a fourth pixel light emitting branch; the second metal layer is defined by the pixel definition layer as a first second metal region comprised in the first pixel light emitting branch, a second second metal region comprised in the second pixel light emitting branch, a third second metal region comprised in the third pixel light emitting branch, and a fourth second metal region comprised in the fourth pixel light emitting branch; the third metal layer is defined by the pixel definition layer as a first third metal region comprised in the first pixel light emitting branch, a second third metal region comprised in the second pixel light emitting branch, a third third metal region comprised in the third pixel light emitting branch, and a fourth third metal region comprised in the fourth pixel light emitting branch; the first type metal electrode is located in the first metal layer, the second type metal electrode is located in the second metal layer, and the third type metal electrode is located in the third metal layer;
the pixel unit comprises two first type metal electrodes, wherein one first type metal electrode bridges the first first metal region and the second first metal region, and the other first type metal electrode bridges the third first metal region and the fourth first metal region; the pixel unit comprises two second type metal electrodes, wherein one second type metal electrode bridges the second second metal region and the fourth second metal region, and the other second type metal electrode bridges the first second metal region and the third second metal region; the pixel unit comprises two third type metal electrodes, wherein one third type metal electrode bridges the first third metal region and the third third metal region, and the other third type metal electrode bridges the second third metal region and the fourth third metal region.

14. The display substrate according to claim 8, wherein the fourth metal layer is distributed on an entire surface.

15. A dark spot repair method of a display substrate, applied to a display substrate according to claim 8, wherein the method comprises:
determining a short-circuited pixel light emitting branch in the display substrate; and
cutting off an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage; wherein the electrode voltage comprises an electrode voltage to which a first metal layer is connected, an electrode voltage to which a second metal layer is connected, and an electrode voltage to which a third metal layer is connected.

16. The method according to claim 15, wherein the cutting off the electrical connection between the light emitting element of each color in the short-circuited pixel light emitting branch and the light emitting element of the remaining pixel light emitting branch in the pixel unit, and the electrical connection between the short-circuited pixel light emitting branch and the electrode voltage, comprises:
cutting off a metal trace between a first metal region in the short-circuited pixel light emitting branch and a first metal region of the remaining pixel light emitting branch in the pixel unit; cutting off a metal trace between a second metal region in the short-circuited pixel light emitting branch and a second metal region of the remaining pixel light emitting branch in the pixel unit; cutting off a metal trace between a third metal region in the short-circuited pixel light emitting branch and a third metal region of the remaining pixel light emitting branch in the pixel unit; and
cutting off a first type metal electrode bridged by a first metal layer in the short-circuited pixel light emitting branch, a second type metal electrode bridged by a second metal layer in the short-circuited pixel light emitting branch, and a third type metal electrode bridged by a third metal layer in the short-circuited pixel light emitting branch.

17. The method according to claim 15, wherein the cutting off the electrical connection between the light emitting element of each color in the short-circuited pixel light emitting branch and the light emitting element of the remaining pixel light emitting branch in the pixel unit, and the electrical connection between the short-circuited pixel light emitting branch and the electrode voltage, comprises:
cutting off a first type metal electrode bridged by a first metal layer in the short-circuited pixel light emitting branch, a second type metal electrode bridged by a second metal layer in the short-circuited pixel light emitting branch, and a third type metal electrode bridged by a third metal layer in the short-circuited pixel light emitting branch.

18. A dark spot repair method of a display substrate, applied to a display substrate according to claim 9, wherein the method comprises:
determining a short-circuited pixel light emitting branch in the display substrate; and
cutting off an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage; wherein the electrode voltage comprises an electrode voltage to which a first metal layer is connected, an electrode voltage to which a second metal layer is connected, and an electrode voltage to which a third metal layer is connected.

19. A dark spot repair method of a display substrate, applied to a display substrate according to claim 10, wherein the method comprises:
determining a short-circuited pixel light emitting branch in the display substrate; and
cutting off an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage; wherein the electrode voltage comprises an electrode voltage to which a first metal layer is connected, an electrode voltage to which a second metal layer is connected, and an electrode voltage to which a third metal layer is connected.

20. A dark spot repair method of a display substrate, applied to a display substrate according to claim 11, wherein the method comprises:
determining a short-circuited pixel light emitting branch in the display substrate; and
cutting off an electrical connection between a light emitting element of each color in the short-circuited pixel light emitting branch and a light emitting element of a remaining pixel light emitting branch in a pixel unit, and an electrical connection between the short-circuited pixel light emitting branch and an electrode voltage; wherein the electrode voltage comprises an electrode voltage to which a first metal layer is connected, an electrode voltage to which a second metal layer is connected, and an electrode voltage to which a third metal layer is connected.
